(19) United States
(12) Patent Application Publication
(10) Pub. No.: US 2015/0001481 A1
(43) Pub. Date: Jan. 1, 2015

(54) ORGANIC ELECTROLUMINESCENT DISPLAY AND METHOD OF MANUFACTURING THE SAME

(71) Applicant: Samsung Display Co., Ltd., Yongin-City (KR)

(72) Inventor: Jung Joo PARK, Seongnam-si (KR)

(73) Assignee: Samsung Display Co., Ltd., Yongin-City (KR)

(21) Appl. No.: 14/078,740

(22) Filed: Nov. 13, 2013

(30) Foreign Application Priority Data
Jun. 27, 2013 (KR) 10-2013-0074803

(51) Int. Cl. H01L 51/52; H01L 27/32; H01L 51/56

(52) U.S. Cl. CPC H01L 51/5237; H01L 51/56; H01L 27/32
USPC 257/40; 438/34

(57) ABSTRACT

An organic electroluminescent display includes a substrate, a first electrode on the substrate, an organic light emitting part on the first electrode and including organic members having a first polarity, a second electrode on the organic light emitting part, and an alignment layer. The alignment layer contacts the organic light emitting part between the first electrode and the second electrode, and has a second polarity opposite to the first polarity. The alignment layer aligns the organic members in the organic light emitting part.

This application claims priority to Korean Patent Application No. 10-2013-0074803, filed on Jun. 27, 2013, and all the benefits accruing therefrom under 35 U.S.C. §119, the contents of which are hereby incorporated by reference in its entirety.

### BACKGROUND

1. Field

The invention relates to an organic electroluminescent display and a method of manufacturing the same. More particularly, the invention relates to an organic electroluminescent display having an improved light-emitting capability and a method of manufacturing the organic electroluminescent display.

2. Description of the Related Art

In general, an organic electroluminescent display includes an anode, an organic light emitting layer disposed on the anode, and a cathode disposed on the organic light emitting layer. The organic electroluminescent display displays an image using a light generated by holes and electrons, which are respectively provided through the anode and the cathode and recombined with each other in the organic light emitting layer.

As an alignment state of organic molecules improves (e.g., is more regular) in the organic light emitting layer, a mobility of the organic molecules is improved. In general, however, the organic molecules are randomly arranged in an organic layer of the organic light emitting layer in order to maintain a stable energy state. Therefore, there remains a need for an improved organic electroluminescent display including an improved mobility of organic molecules having a stable energy state.

### SUMMARY

One or more exemplary embodiment of the invention provides an organic electroluminescent display having an improved light-emitting capability.

One or more exemplary embodiment of the invention provides a method of manufacturing the organic electroluminescent display.

An exemplary embodiment of the invention provides an organic electroluminescent display including a substrate, a first electrode, an organic light emitting part, a second electrode and an alignment layer. The first electrode is on the substrate. The organic light emitting part is on the first electrode and includes first organic members having a first polarity. The second electrode is on the organic light emitting part. The alignment layer contacts the organic light emitting part between the first electrode and the second electrode, and includes second organic members having a second polarity opposite to the first polarity. The alignment layer aligns the first organic members in the organic light emitting part.

An exemplary embodiment of the invention provides a method of manufacturing an organic electroluminescent display including forming an alignment layer including first organic members having a first polarity, on a substrate; providing second organic members having a second polarity opposite to the first polarity, to the alignment layer, to form an organic light emitting part including the second organic members on the alignment layer; aligning the second organic members in the organic light emitting part on the alignment layer; and forming a second electrode on the organic light emitting part. The second organic members are aligned by an attractive force generated between the alignment layer and the second organic members when the organic light emitting part is formed on the alignment layer.

According to one or more exemplary embodiment of the invention, the organic members (which may be otherwise referred to as organic molecules) of the organic light emitting layer are easily aligned using the attractive force and the ionic bond between the organic members of the alignment layer and the organic molecules of the organic light emitting layer while the organic light emitting layer is formed on the alignment layer, by providing the organic molecules of the organic light emitting layer to the alignment layer. Thus, the organic light emitting layer may have electrical characteristics within a crystalline structure and the mobility of the organic light emitting layer is improved, thereby improving the light emitting efficiency of the organic electroluminescent layer.

### BRIEF DESCRIPTION OF THE DRAWINGS

The above and other advantages of the disclosure will become readily apparent by reference to the following detailed description when considered in conjunction with the accompanying drawings wherein:

FIG. 1 is a cross-sectional view showing an exemplary embodiment of a pixel of an organic electroluminescent display according to the invention;

FIG. 2 is a partially enlarged view of an exemplary embodiment of a first portion A1 shown in FIG. 1;

FIG. 3 a cross-sectional view showing another exemplary embodiment of a pixel of an organic electroluminescent display according to the invention;

FIGS. 4A to 4F are cross-sectional views showing an exemplary embodiment of a method of manufacturing the organic electroluminescent display shown in FIG. 1; and

FIG. 5 is a cross-sectional view showing another exemplary embodiment of a method of forming an alignment layer in the organic electroluminescent display shown in FIG. 1 according to the invention.

### DETAILED DESCRIPTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be explained in detail with reference to the accompanying drawings.

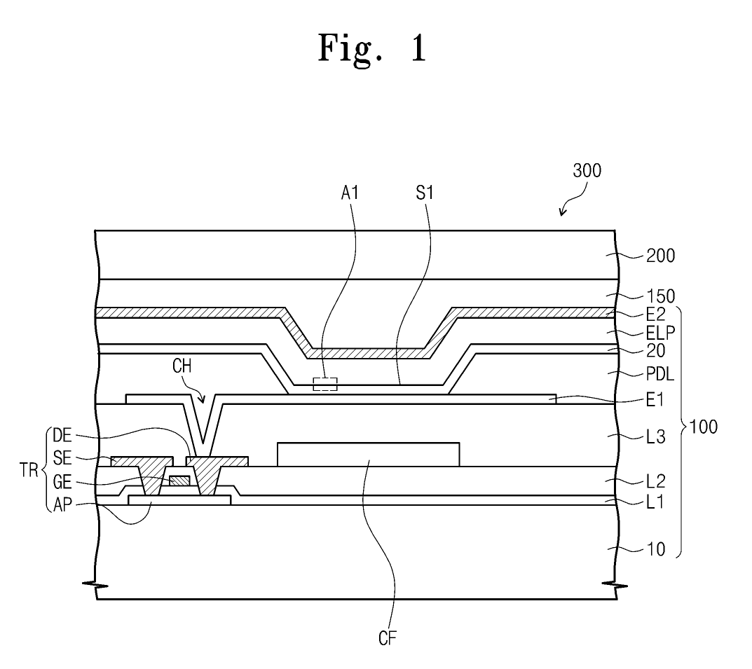

FIG. 1 is a cross-sectional view showing an exemplary embodiment of a pixel of an organic electroluminescent display according to the invention.

Referring to FIG. 1, an organic electroluminescent display 300 includes a display substrate 100, and an opposite substrate 200 facing the display substrate 100. The opposite substrate 200 is coupled to the display substrate 100 to reduce or effectively prevent entry of humidity and gas (e.g., moisture and air) into the display substrate 100 from outside of the display substrate 100. According to another exemplary embodiment, the opposite substrate 200 may be omitted from the organic electroluminescent display 300. Where the opposite substrate 200 is omitted from the organic electroluminescent display 300, a sealant layer (not shown) is provided on the display substrate 100 to cover the display substrate 100, thereby reducing or effectively preventing entry of the humidity and gas into the display substrate 100.

The display substrate 100 includes a substrate 10 which may be otherwise referred to as a base substrate, a thin film transistor TR, a first electrode E1, a color filter CF, a pixel definition layer PDL, an alignment layer 20, an organic light emitting part ELP and a second electrode E2. In an exemplary embodiment, one or more of the aforementioned elements may be included in the display substrate 100, and the reference numbers described above may refer to one or more of such elements. In the illustrated exemplary embodiment, the organic electroluminescent display 300 is a rear surface light emitting type, and thus light emitted from the organic light emitting part ELP travels to the outside of the substrate 10 after passing through the substrate 10. To this end, the substrate 10 may include a transparent insulating substrate, e.g., a glass substrate, a plastic substrate, etc. In addition, when the substrate 10 includes one of the aforementioned materials such as to be the plastic substrate, the substrate 10 may have flexibility.

The thin film transistor TR is disposed on the substrate 10 and electrically connected to the first electrode E1, to switch a driving signal applied to the first electrode E1. The thin film transistor TR includes an active pattern AP, a gate electrode GE, a source electrode SE and a drain electrode DE.

The source electrode SE is physically and/or electrically connected to a driving signal line (not shown), through which the driving signal is transmitted, and overlapped with the active pattern AP. The drain electrode DE is overlapped with the active pattern AP and physically and/or electrically connected to the first electrode E1. Thus, when the thin film transistor TR is turned on, the driving signal is applied to the first electrode E1 through the driving signal line and the thin film transistor TR.

In the illustrated exemplary embodiment, the active pattern AP includes a semiconductor material, e.g., amorphous silicon or crystalline silicon, but is not be limited thereto or thereby. In an exemplary embodiment, for instance, the active pattern AP may include an oxide semiconductor material, such as indium gallium zinc oxide (“IGZO”), ZnO, SnO₂, In₂O₃, Zn₂SnO₄, Ge₂O₃, HfO₂, etc., or a compound semiconductor material, such as GaAs, GaP, InP, etc.

A gate insulating layer L1 is disposed between the gate electrode GE and the active pattern AP, and an inter-insulating layer L2 covers the gate electrode GE to respectively insulate the gate electrode GE from the source and drain electrodes SE and DE. A planarization layer L3 covers the thin film transistor TR, and a contact hole CH is defined extending through a thickness thereof. The first electrode E1 is electrically connected to the drain electrode DE through the contact hole CH.

The first electrode E1 is disposed on the planarization layer L3 and serves as an anode. In addition, when the organic electroluminescent display 300 is the rear surface light-emitting type, the first electrode E1 may be a transparent conductive layer, e.g., indium tin oxide, indium zinc oxide, etc.

The pixel definition layer PDL is disposed on the planarization layer L3 and the first electrode E1. An opening is defined in the pixel definition layer PDL to correspond to the first electrode E1. The opened portion of the pixel definition layer PDL may expose a portion of the first electrode EL. Accordingly, the alignment layer 20 and the organic light emitting part ELP may be sequentially stacked on the first electrode E1 in the opened portion of the pixel definition layer PDL.

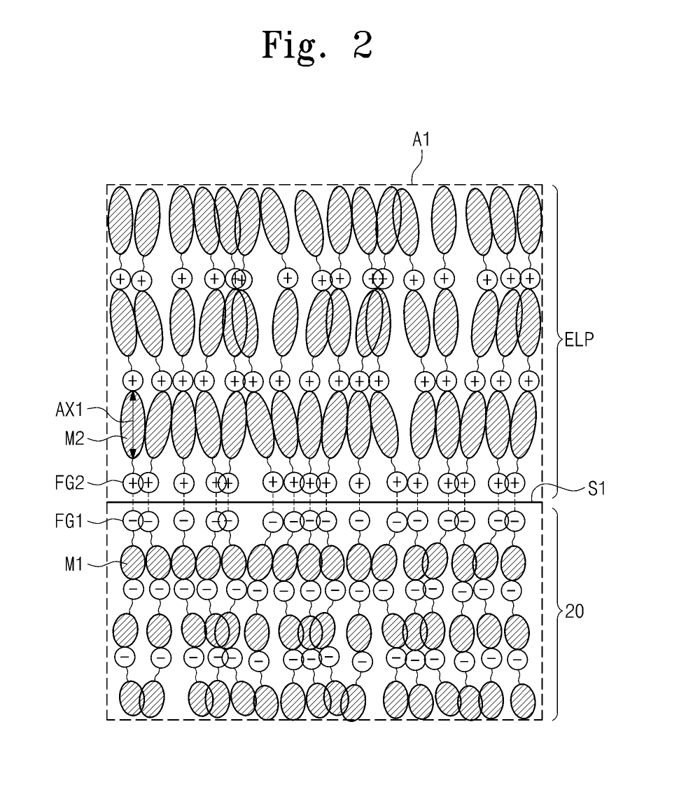

The alignment layer 20 is disposed between the first electrode E1 and the organic light emitting part ELP. An interface S1 is defined between the alignment layer 20 and the organic light emitting part ELP, and the alignment layer 20 makes contact with the organic light emitting part ELP at the interface S1. The alignment layer 20 is charged to an electrical polarity different from the organic molecules of the organic light emitting part ELP to align the organic molecules of the organic light emitting part ELP. The alignment layer 20 will be described in detail with reference to FIG. 2.

The organic light emitting part ELP is disposed on the alignment layer 20, and the second electrode E2 is disposed on the organic light emitting part ELP to serve as a cathode. In the illustrated exemplary embodiment, the organic light emitting part ELP may include an organic light emitting layer. As an organic light emitting layer, holes provided from the first electrode E1 are recombined with electrons provided from the second electrode E2 in the organic light emitting part ELP, and thus the organic light emitting part ELP emits the light.

In the illustrated exemplary embodiment, the light emitted from the organic light emitting part ELP may be a white light. The organic light emitting part ELP has a single-layer structure (e.g., monolayer) having a continuous form, and is disposed over both a non-pixel area and a pixel area of the organic electroluminescent display 300, but the structure of the organic light emitting part ELP should not be limited thereto or thereby. According to another exemplary embodiment, the organic light emitting part ELP may have a patterned shape (e.g., discontinuous form) in the pixel area and/or may have a multi-layer structure including a hole injection layer, an electron injection layer and the organic light emitting layer.

The color filter CF is disposed on the substrate 10 to filter the light emitted from the organic light emitting part ELP to be a color light. When the light emitted from the organic light emitting part ELP is the white light, the white light is converted to the color light by passing through the color filter CF, and the color light travels to the outside of the substrate 10.

The second electrode E2 is disposed on the organic light emitting part ELP. When the organic electroluminescent display 300 is the rear surface light-emitting type, the second electrode E2 includes a conductive material having a reflectivity to the light, e.g., a metal material. Therefore, the light emitted from the organic light emitting part ELP is reflected by the second electrode E2 and travels to the color filter CF.

In the illustrated exemplary embodiment, a protective layer 150 is disposed between the display substrate 100 and the opposite substrate 200. The protective layer 150 includes a polymer, such as a polyimide resin, and reduces or effectively prevents entry of humidity and gas from into the display substrate 100.

FIG. 2 is a partially enlarged view of an exemplary embodiment of a first portion A1 shown in FIG. 1.

Referring to FIG. 2, the interface S1 is defined between the organic light emitting part ELP and the alignment layer 20, and the organic light emitting part ELP makes contact with the alignment layer 20 at the interface S1. In the illustrated exemplary embodiment, the alignment layer 20 includes first organic members M1 which may be otherwise referred to as first organic molecules, charged to a negative polarity. In one exemplary embodiment, for instance, the first organic molecules M1 includes a negative ion functional group FG1, e.g., a carboxyl group, a sulfonic acid group, etc., and is charged to the negative polarity.

The organic light emitting part ELP includes second organic members M2 which may be otherwise referred to as second organic molecules, charged to a positive polarity. In one exemplary embodiment, for instance, the second organic molecules M2 includes a positive ion functional group FG2, e.g., an amino group, an imino group, etc., and is charged to the positive polarity.

According to the structure of the alignment layer 20 and the organic light emitting part ELP, the second organic molecules M2 are ionic-bonded to the first organic molecules M1 at the interface S1. Where the second organic molecules M2 are ionic-bonded to the first organic molecules M1, a bonding force of the ionic bond acts along a direction slightly tilted with respect to a normal line direction of the interface S1, but the direction along which the bonding force of the ionic bond acts is substantially in parallel to the normal line direction of the interface S1. In addition, a position of the positive ion functional group FG2 is uniform in each of the second organic molecules M2. Therefore, the second organic molecules M2 bonded to the first organic molecules M1 at the interface S1 are aligned to the normal line direction. In detail, when each of the second organic molecules M2 has a structure extended in a long axis direction AX1 thereof and the positive ion functional group FG2 is connected to an edge in the long axis direction AX1 of the second organic molecules M2, the long axis direction AX1 may be substantially in parallel to the normal line direction of the interface S1 by the bonding force of the ionic bond. Accordingly, the second organic molecules M2 may be aligned in the organic light emitting part ELP, in the direction substantially in parallel to the normal line direction of the interface S1.

Further, since each of remaining second organic molecules M2 among the second organic molecules M2, which is not involved in the ionic bond, effectively has two different polarities in the long axis direction AX1 due to the positive ion functional group FG2, the remaining second organic molecules M2 may be aligned such that the long axis direction AX1 thereof is also substantially in parallel to the normal line direction of the interface S1.

As described above, when the second organic molecules M2 are aligned in the direction substantially in parallel to the normal line direction of the interface S1 by the alignment layer 20, the organic light emitting part ELP may have electrical characteristics within a crystalline structure. In more detail, the overlap between orbitals is increased since the second organic molecules M2 are aligned in the specific direction (e.g., regularly arranged), and thus electrons easily move in the organic light emitting part ELP. This means that the mobility of the organic light emitting part ELP is improved by the alignment of the second organic molecules M2. Therefore, the light emitting capability, which is caused by the recombination of the holes and the electrons in the organic light emitting part ELP, may be improved.

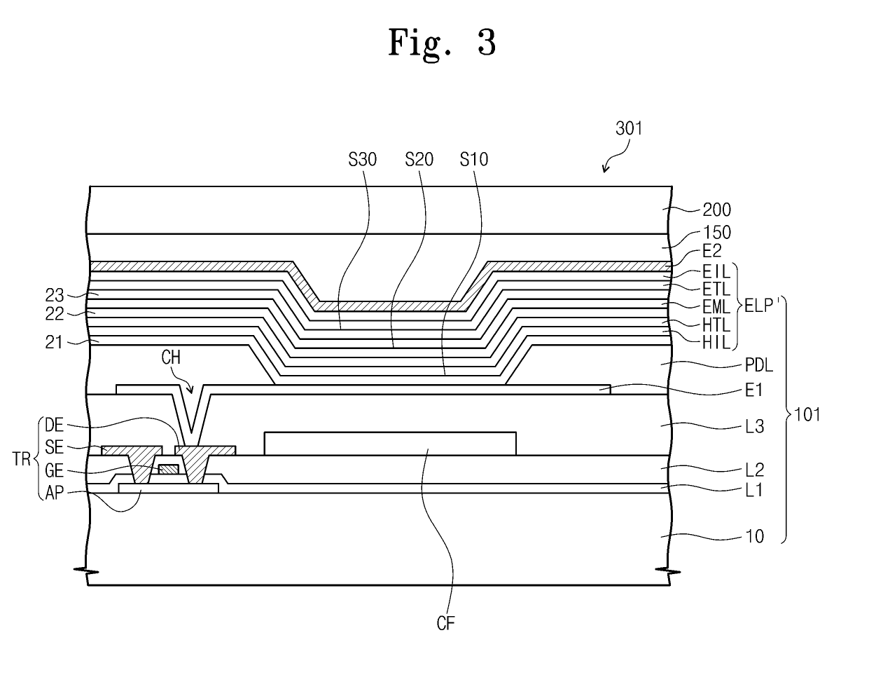

FIG. 3 a cross-sectional view showing another exemplary embodiment of a pixel of an organic electroluminescent display according to the invention. In FIG. 3, the same reference numerals denote the same elements in FIGS. 1 and 2, and thus detailed descriptions of the same elements will be omitted.

Referring to FIG. 3, an organic electroluminescent display 301 includes a display substrate 101 and an opposite substrate 200, and the display substrate 101 includes an organic light emitting part ELF.

In the illustrated exemplary embodiment, the organic light emitting part ELF includes a hole injection layer HIL, a hole transport layer HTL, an organic light emitting layer EML, an electron transport layer ETL, and an electron injection layer EIL, which are sequentially stacked on a first electrode E1. In addition, a first alignment layer 21 is disposed between the first electrode E1 and the hole injection layer HIL, a second alignment layer 22 is disposed between the hole transport layer HTL and the organic light emitting layer EML, and a third alignment layer 23 is disposed between the organic light emitting layer EML and the electron transport layer ETL.

In the illustrated exemplary embodiment, similar to the alignment layer 20 described with reference to FIGS. 1 and 2, each of the first, second and third alignment layers 21, 22 and 23 includes a material charged to the negative polarity. Where each of the first, second and third alignment layers 21, 22 and 23 includes a material charged to the negative polarity, the hole injection layer HIL includes organic molecules charged to the positive polarity, so that the ionic bond is induced at a first interface S10 between the hole injection layer HIL and the first alignment layer 21. Thus, as the second organic molecules M2 (refer to FIG. 2), the organic molecules are aligned to a normal line direction of the first interface S10 in the hole injection layer HIL, thereby improving the mobility in the hole injection layer HIL.

In addition, each of the organic light emitting layer EML and the electron transport layer HTL includes organic molecules charged to the positive polarity, and thus the ionic bond may be induced at a second interface S20 and a third interface S30, respectively. Therefore, the organic molecules are respectively aligned to the normal line direction of the second and third interfaces S20 and S30 in the organic light emitting layer EML and the electron transport layer HTL, to thereby improve the mobility in the organic light emitting layer EML and the electron transport layer HTL.

In the illustrated exemplary embodiment, the first, second and third alignment layers 21, 22 and 23 are included in the organic light emitting part ELP′, but an additional alignment layer may be disposed between the hole transport layer HTL and the hole injection layer HIL and/or between the electron transport layer ETL and the electron injection layer EIL.

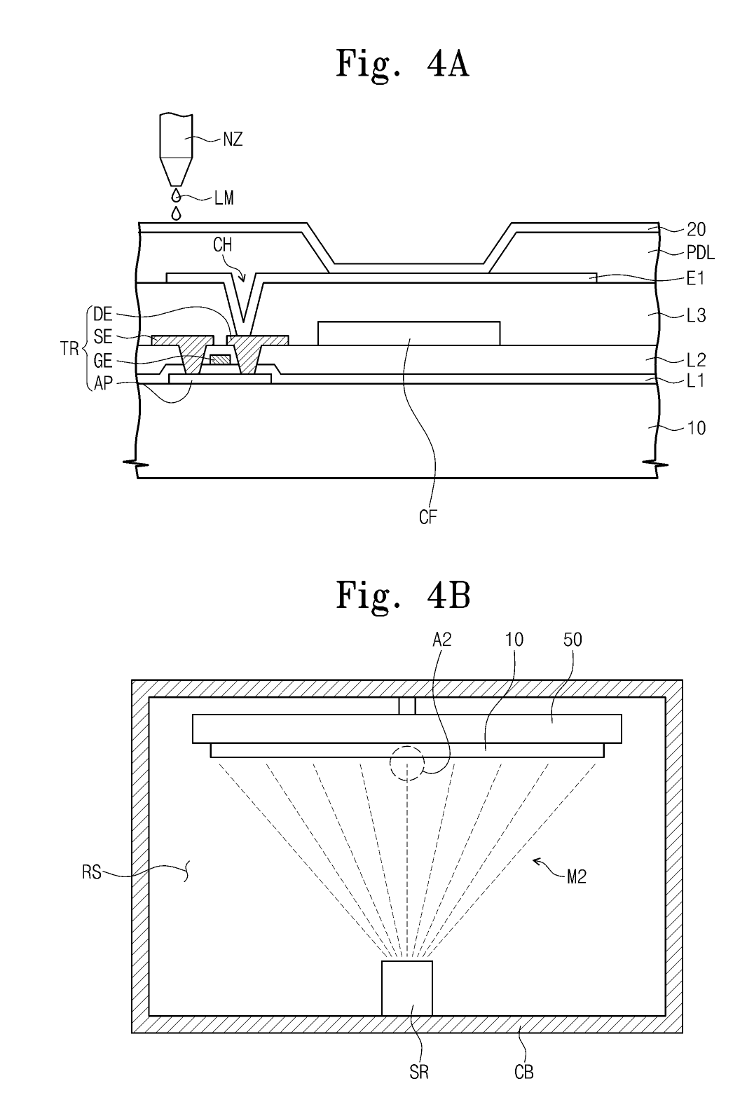

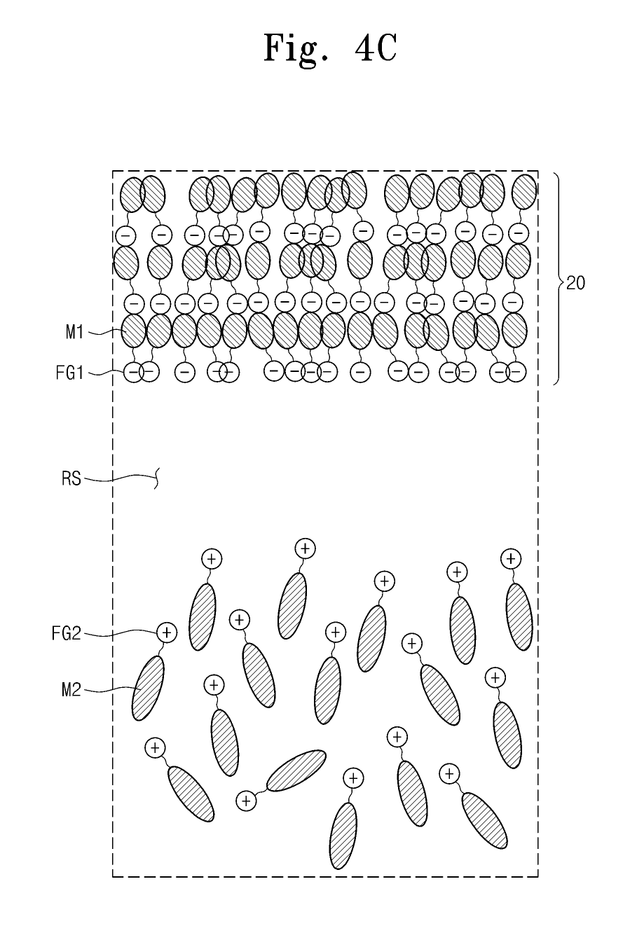

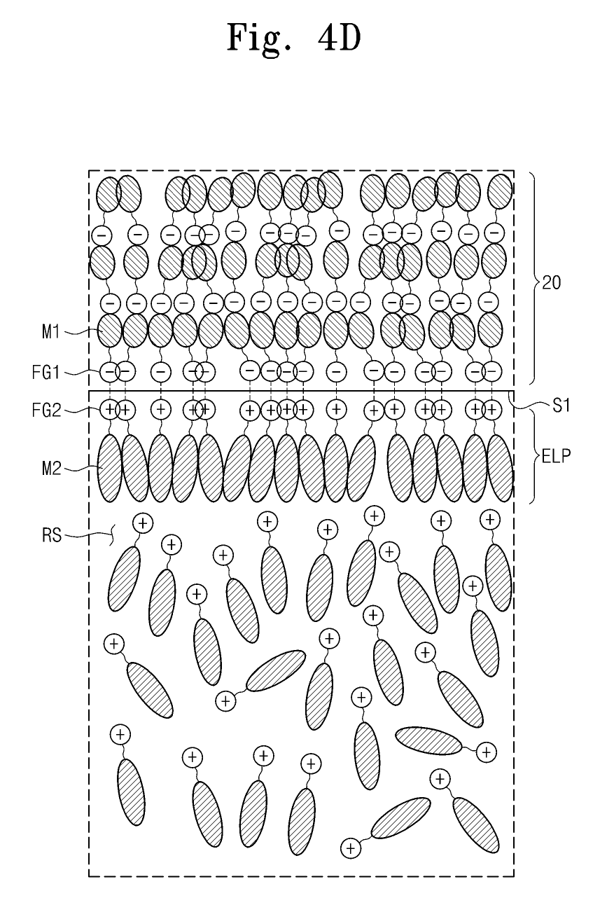

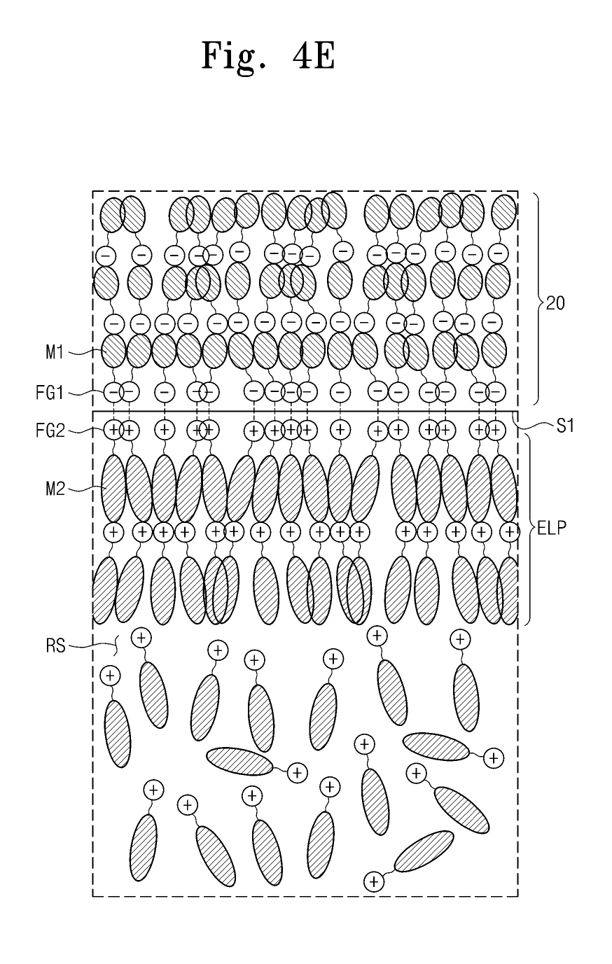

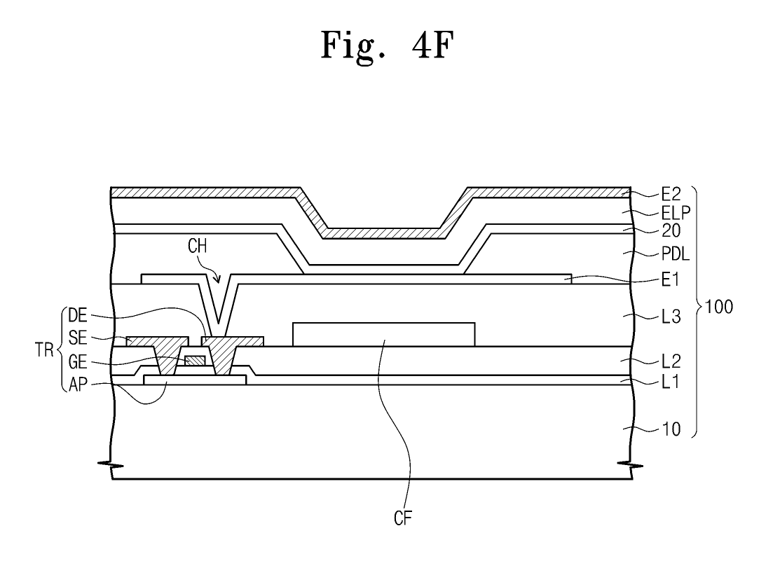

FIGS. 4A to 4F are views showing an exemplary embodiment of a method of manufacturing the organic electroluminescent display shown in FIG. 1. FIG. 4C and 4D are partially enlarged views of an exemplary embodiment of a second portion A2 shown in FIG. 4A.

Hereinafter, an exemplary embodiment of a method of forming the alignment layer 20 will be described in detail with reference to FIG. 4A. Referring to FIG. 4A, the thin film transistor TR, the color filter CF, the first electrode E1 electrically connected to the thin film transistor TR, and the pixel definition layer PDL are formed (e.g., provided) on the substrate 10. A liquefied material LM is provided to the substrate 10 using a nozzle NZ to form an alignment material layer (indicated by 20 in FIG. 4A) on the first electrode E1 and the pixel definition layer PDL.

In the illustrated exemplary embodiment, the liquefied material LM is manufactured by melting a solid material including the first organic molecules M1 (refer to FIG. 2) charged to the negative polarity in solvent, and the liquefied material LM is provided to the substrate 10 using an inkjet method or a slit coating method. In addition, after the liquefied material LM is provided to the substrate 10 as the alignment material layer, a heat-treatment process is performed on the substrate 10 to remove the solvent from the liquefied material LM to form the alignment layer 20.

Referring to FIG. 4B, the substrate 10 including the alignment layer 20 thereon (refer to FIG. 4A) is indicated generally as 10, and is placed on a substrate supporter 50 in a chamber CB. The alignment layer 20 (refer to FIG. 4A) formed on the substrate 10 is exposed to a reaction space RS of the chamber CB while the substrate 10 including the alignment layer 20 thereon is supported by the substrate supporter 50.

The reactive space RS is maintained in a vacuum state by using a vacuum pump (not shown) connected to the reactive space RS, and a deposition source SR disposed on a bottom portion of the chamber CB is heated. The deposition source SR may include a source material and the second organic molecules M2. The deposition source SR is manufactured by using the organic material including the organic molecules charged to the positive polarity in a power shape. When the deposition source SR is heated, the source material in the deposition source SR is evaporated and the second organic molecules M2 exit from the deposition source SR. As a result, the second organic molecules M2 exiting from the deposition source SR are provided to the substrate 10 after passing through the reactive space RS, and the second organic molecules M2 are deposited on the alignment layer 20 (refer to FIG. 4A) formed on the substrate 10, thereby forming the organic light emitting part ELP (refer to FIG. 1).

Hereinafter, an exemplary embodiment of a process of forming the organic light emitting part ELP will be described in detail with reference to FIGS. 4B, 4C, 4D and 4E.

Referring to FIGS. 4B and 4C, the alignment layer 20 formed on the substrate 10 is exposed to the reactive space RS and the second organic molecules M2 exiting from the deposition source SR travel toward the substrate 10 after passing through the reactive space RS.

As described above, although the second organic molecules M2 are charged to the positive polarity, the second organic molecules M2 may randomly exist in the reactive space RS as illustrated in FIG. 4C since any element that causes an electrical operation with respect to the second organic molecules M2 does not exist in the reactive space RS.

Referring to FIGS. 4B and 4D, when a portion of the second organic molecules M2 reaches the alignment layer 20, an attractive force occurs between the negative ion functional group FG1 of the first organic molecules M1 and the positive ion functional group FG2 of the second organic molecules M2. As a result, due to the attractive force, the second organic molecules M2 are aligned to allow the positive ion functional group FG2 to face the negative ion functional group FG1, and the second organic molecules M2 are ionic-bonded to the first organic molecules M1 at the interface 51 between the alignment layer 20 and the organic light emitting part ELP.

Accordingly, the second organic molecules M2 are deposited on the alignment layer 20 to form the organic light emitting part ELP and the interface 51 is defined between the organic light emitting part ELP and the alignment layer 20. The second organic molecules M2 are aligned at the interface S1 along the normal line direction of the interface S1. These second organic molecules M2 aligned at the interface S1 may be otherwise referred to as base or initial second organic molecules M2.

Referring to FIGS. 4B and 4E, further second organic molecules M2 are deposited on the initial second organic molecules M2 ionic-bonded to the first organic molecules M1 at the interface

S1, to continue forming the organic light emitting part ELP by deposition. Since each of the second organic molecules M2 effectively has two different polarities in the long axis direction by the positive ion functional group FG2, the further second organic molecules M2 are aligned such that the long axis direction of the further second organic molecules M2 is substantially in parallel to the normal line direction of the interface S1 while forming the organic light emitting part ELP proceeds.

Referring to FIG. 4F, once the organic light emitting part ELP is formed by depositing the second organic molecules M2 (refer to FIG. 4B) on the alignment layer 20 (refer to FIG. 4A), the second electrode E2 is formed on the organic light emitting part ELP, thereby manufacturing the display substrate 100.

The protective layer 150 (refer to FIG. 1) is formed to cover the second electrode E2, and the opposite substrate 200 (refer to FIG. 1) is coupled to the display substrate 100 while interposing the protective layer therebetween, to thereby manufacture the organic electroluminescent display 300 (refer to FIG. 1).

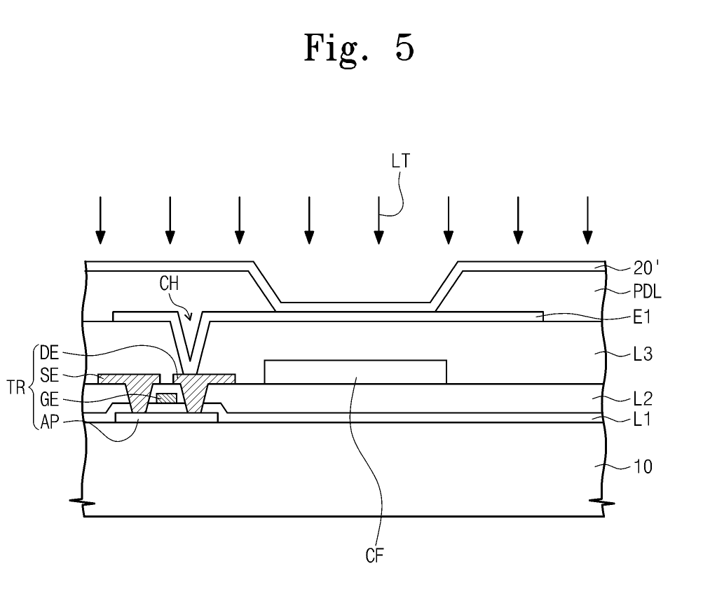

FIG. 5 is a cross-sectional view showing another exemplary embodiment of a method of forming the alignment layer with respect to FIG. 4A according to the invention.

Referring to FIG. 4A and FIG. 5, the liquefied material LM includes non-polarity molecules, and is provided onto the substrate 10 using the spin coating method or the slit coating method to form a preliminary alignment layer 20′.

Then, a light LT having energy greater than ionization energy of the non-polarity molecules, e.g., a laser beam, is irradiated onto the preliminary alignment layer 20′. By irradiating the light LT onto the preliminary alignment layer 20′, the non-polarity molecules of the preliminary alignment layer 20′ absorb the energy of the light LT to discharge electrons, thereby forming the alignment layer charged to the positive polarity.

As described above, when the alignment layer charged to the positive polarity is formed, the organic molecules of the organic light emitting part ELP are charged to the negative polarity in order to induce the ionic bond between the molecules of the alignment layer and the organic molecules of the organic light emitting part ELP (refer to FIG. 1).

The method of charging the alignment layer to have the electrical polarity should not be limited thereto or thereby. In one exemplary embodiment, for instance, the alignment layer may have a positive or negative electrical property using an ion injection method.

Although exemplary embodiments of the invention have been described, it is understood that the invention should not be limited to these exemplary embodiments but various changes and modifications can be made by one ordinary skilled in the art within the spirit and scope of the invention as hereinafter claimed.

What is claimed is:

1. An organic electroluminescent display comprising:
a substrate;
a first electrode on the substrate;
an organic light emitting part on the first electrode and comprising first organic members having a first polarity;
a second electrode on the organic light emitting part; and
an alignment layer which contacts the organic light emitting part between the first electrode and the second electrode, and comprising second organic members having a second polarity opposite to the first polarity, wherein the alignment layer aligns the first organic members in the organic light emitting part.

2. The organic electroluminescent display of claim 1, wherein the first organic members of the organic light emitting part are ionic-bonded to the second organic members of the alignment layer, at an interface between the alignment layer and the organic light emitting part.

3. The organic electroluminescent display of claim 2, wherein the first organic members are aligned in the organic light emitting part, in a direction of the ionic bond.

4. The organic electroluminescent display of claim 2, wherein the first organic members are aligned in the organic light emitting part, in a direction normal to the interface between the alignment layer and the organic light emitting part.

5. The organic electroluminescent display of claim 1, wherein
the organic light emitting part further comprises an organic light emitting layer, and
the alignment layer is between the first electrode and the organic light emitting layer, and contacts the organic light emitting layer.

6. The organic electroluminescent display of claim 5, wherein the organic light emitting part further comprises:
a hole injection layer between the first electrode and the organic light emitting layer;
a hole transport layer between the hole injection layer and the organic light emitting layer;
an electron injection layer between the organic light emitting layer and the second electrode; and
an electron transport layer between the electron injection layer and the organic light emitting layer, and
the alignment layer is between the first electrode and the hole injection layer, between the hole injection layer and the hole transport layer, between the hole transport layer and the organic light emitting layer, between the organic light emitting layer and the electron transport layer, or between the electron transport layer and the electron injection layer.

7. A method of manufacturing an organic electroluminescent display, comprising:
forming an alignment layer comprising first organic members having a first polarity, on a substrate;
providing second organic members having a second polarity opposite to the first polarity, to the alignment layer, to form an organic light emitting part comprising the second organic members on the alignment layer;
aligning the second organic members in the organic light emitting part on the alignment layer; and
forming a second electrode on the organic light emitting part,
wherein the second organic members are aligned by an attractive force generated between the alignment layer and the second organic members when the organic light emitting part is formed on the alignment layer.

8. The method of claim 7, wherein the aligning the second organic members comprises ionic-bonding the second organic members to the first organic members of the alignment layer, at an interface between the alignment layer and the organic light emitting part.

9. The method of claim 8, wherein the second organic members are aligned in the organic light emitting part in a direction of the ionic bond.

10. The method of claim 8, wherein the second organic members are aligned in the organic light emitting part in a direction normal to the interface between the alignment layer and the organic light emitting part.

11. The method of claim 7, wherein the forming the alignment layer on the substrate comprises providing a liquefied material having the first polarity onto the substrate.

12. The method of claim 7, wherein the forming the alignment layer onto the substrate comprises:
forming a preliminary alignment layer on the substrate; and
irradiating a light onto the preliminary alignment layer to charge the preliminary alignment layer to the first polarity and form the alignment layer comprising the first organic members having the first polarity.

13. The method of claim 7, wherein the forming the organic light emitting part on the alignment layer comprises forming an organic light emitting layer on the alignment layer using an evaporation method.

14. The method of claim 13, wherein
the forming the organic light emitting part on the alignment layer further comprises:
forming a hole injection layer between the first electrode and the organic light emitting layer;
forming a hole transport layer between the hole injection layer and the organic light emitting layer;
forming an electron injection layer between the organic light emitting layer and the second electrode; and
forming an electron transport layer between the electron injection layer and the organic light emitting layer, and
the alignment layer is between the first electrode and the hole injection layer, between the hole injection layer and the hole transport layer, between the hole transport layer and the organic light emitting layer, between the organic light emitting layer and the electron transport layer, or between the electron transport layer and the electron injection layer.
